(19) United States
(12) Patent Application Publication
(10) Pub. No.: US 2019/0115451 A1
(43) Pub. Date: Apr. 18, 2019

(54) METHODS OF FABRICATING SEMICONDUCTOR DEVICE

(71) Applicant: Samsung Electronics Co., Ltd., Suwon-si (KR)

(72) Inventors: Joon Gon Lee, Seoul (KR); Kuo Tai Huang, Seongnam-si (KR); Ryuji Tomita, Yongin-si (KR)

(21) Appl. No.: 16/051,635

(22) Filed: Aug. 1, 2018

(30) Foreign Application Priority Data
Oct. 17, 2017 (KR) 10-2017-0134699

(51) Int. Cl. H01L 29/66; H01L 21/8238; H01L 21/8234; H01L 21/308; H01L 23/532; H01L 29/08; H01L 29/423

(52) U.S. Cl. CPC H01L 29/66636; H01L 29/6681; H01L 21/823814; H01L 21/823864; H01L 29/42364; H01L 21/308; H01L 23/5329; H01L 29/0847; H01L 21/823431

(57) ABSTRACT

Methods of fabricating a semiconductor device are provided. The methods may include forming an active pattern on a substrate, forming a gate electrode traversing the active pattern on the active pattern, forming a recess adjacent to a sidewall of the gate electrode in the active pattern, and performing a chemical vapor deposition process using a source gas and a doping gas to form a source/drain region in the recess. The source gas may include a silicon precursor and a germanium precursor, and the doping gas may include a gallium precursor and a boron precursor.

### CROSS-REFERENCE TO RELATED APPLICATION

This application claims priority under 35 U.S.C. § 119 to Korean Patent Application No. 10-2017-0134699 filed on Oct. 17, 2017, in the Korean Intellectual Property Office, the disclosure of which is incorporated herein by reference in its entirety.

### BACKGROUND

The present inventive concept relates to methods of fabricating a semiconductor device.

Various research has been conducted to lower manufacturing cost of semiconductor devices and to increase integration density of semiconductor devices.

As the semiconductor products are highly integrated, lowering the resistance of a source/drain contact of a transistor may be beneficial. The resistance of the source/drain contact may be affected by a height of a Schottky barrier. Therefore, the resistance of the source/drain contact may be lowered by adjusting the work function of silicide and/or lowering the height of the Schottky barrier using doping.

### SUMMARY

Aspects of the present inventive concept provide methods of fabricating a semiconductor device having lower contact resistance.

According to aspects of the present inventive concept, a method of fabricating a semiconductor device is provided. The method may include forming an active pattern on a substrate, forming a gate electrode traversing the active pattern on the active pattern, forming a recess adjacent to a sidewall of the gate electrode in the active pattern, and performing a chemical vapor deposition process using a source gas and a doping gas to form a source/drain region in the recess. The source gas may include a silicon precursor and a germanium precursor, and the doping gas may include a gallium precursor and a boron precursor.

According to aspects of the present inventive concept, a method of fabricating a semiconductor device. The method may include forming an active pattern on a substrate, forming a gate electrode traversing the active pattern on the active pattern, forming a recess adjacent a sidewall of the gate electrode in the active pattern, and forming a source/drain region in the recess by performing an epitaxial growth process and a doping process in-situ. The source/drain region may include Si₁₋ₓGeₓ doped with gallium and boron.

According to aspects of the present inventive concept, a method of fabricating a semiconductor device is provided. The method may include forming a first active pattern and a second active pattern on a substrate, forming a first recess in the first active pattern, forming a first source/drain region including p-type impurities in the first recess by performing a first epitaxial growth process and a first doping process concurrently, forming a second recess in the second active pattern, performing a second epitaxial growth process to form a second source/drain region in the second recess, and performing a second doping process to dope first n-type impurities into the second source/drain region, after forming the second source/drain region. The first source/drain region including the p-type impurities may be formed without performing a doping process for doping the p-type impurities into the first source/drain region after forming the first source/drain region.

### BRIEF DESCRIPTION OF THE DRAWINGS

FIGS. 1, 2, 3, 4, 5, 6, 7, and 8 are view illustrating a method of fabricating a semiconductor device according to some embodiments of the present inventive concept.

FIGS. 9, 10, 11, 12, 13, and 14 are view illustrating a method of fabricating a semiconductor device according to some embodiments of the present inventive concept.

FIGS. 15, 16, 17, 18, 19, 20, 21, 22, 23, 24, and 25 are view illustrating a method of fabricating a semiconductor device according to some embodiments of the present inventive concept.

FIG. 26 is a view illustrating a method of fabricating a semiconductor device according to some embodiments of the present inventive concept.

### DETAILED DESCRIPTION

Advantages and features of the present inventive concept and methods of accomplishing the same may be understood by reference to the following detailed description and the accompanying drawings. The present inventive concept may, however, be embodied in many different forms and should not be construed as being limited to the embodiments set forth herein. In the drawings, thickness of layers and/or regions may be exaggerated for clarity. Like reference numbers refer to like elements throughout.

As used herein the term “and/or” includes any and all combinations of one or more of the associated listed items. It will be understood that “two processes being performed in-situ” means that the two processes are concurrently performed in a single process chamber. It will be also understood that “two processes being performed concurrently” means that the two processes are performed at approximately (but not necessarily exactly) the same time.

A method of fabricating a semiconductor device according to some embodiments of the present inventive concept will be described with reference to FIGS. 1 to 8.

FIGS. 1 to 8 are view illustrating a method of fabricating a semiconductor device according to some embodiments of the present inventive concept.

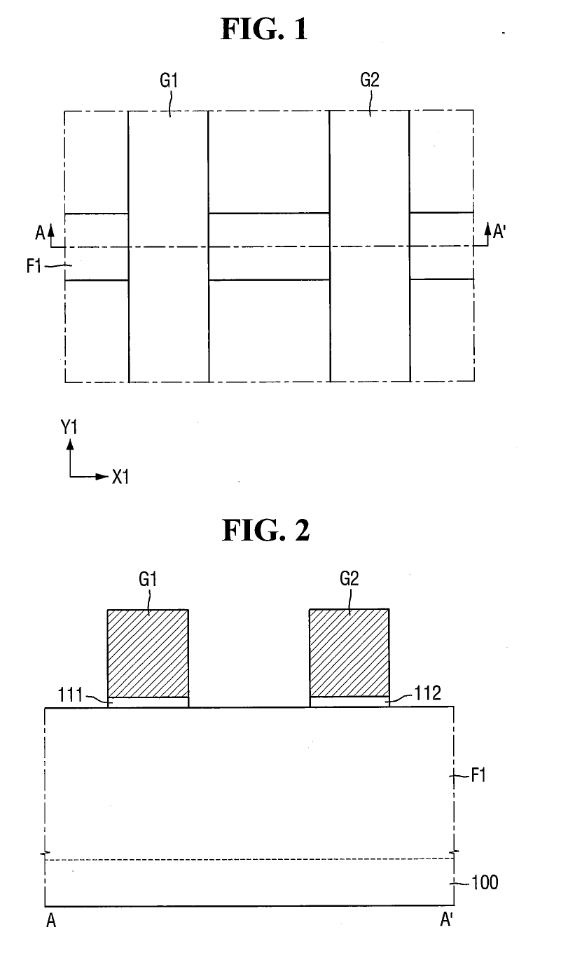

FIG. 1 is a layout illustrating the method of fabricating the semiconductor device according to some embodiments of the present inventive concept. FIGS. 2 through 8 are cross-sectional views taken along the line A-A′ of FIG. 1.

Referring to FIGS. 1 and 2, a first fin type pattern F1 is formed on a substrate 100.

The substrate 100 may be, for example, a bulk silicon substrate or a silicon-on-insulator (SOI) substrate. The substrate 100 may be a silicon substrate or may include other materials, for example, silicon-germanium, indium antimonide, lead telluride, indium arsenide, indium phosphide, gallium arsenide, and/or gallium antimonide. In some embodiments, the substrate 100 may have an epitaxial layer formed on a base substrate.

The first fin type pattern F1 may protrude from the substrate 100 and extend in a first direction X1. The first pin-type pattern F1 may be a part of the substrate 100 and may include an epitaxial layer that is grown from the substrate 100. The first pin-type pattern F1 may be an active pattern of a transistor and may have a fin shape.

The first fin type pattern F1 may include, for example, silicon and/or germanium which is an elemental semiconductor material. Further, the first fin type pattern F1 may include a compound semiconductor, for example, a group IV-IV compound semiconductor or a group III-V compound semiconductor.

In some embodiments, the first fin type pattern F1 may include a group IV-IV compound semiconductor and may include a binary compound or a ternary compound containing at least two or more of carbon (C), silicon (Si), germanium (Ge), and tin (Sn), or a compound obtained by doping these elements with the group IV elements. In some embodiments, the first fin type pattern F1 may include a group III-V compound semiconductor and may include one of a binary compound, a ternary compound or a quaternary compound formed by combination of at least one of aluminum (Al), gallium (Ga), and indium (In) as a group III element with one of phosphorus (P), arsenic (As), and antimony (Sb) as a group V element. In some embodiments, the first fin type pattern F1 will be described as a silicon fin type pattern including silicon.

A first gate insulating film 111, a second gate insulating film 112, a first gate electrode G1, and a second gate electrode G2 are formed on the first fin type pattern F1.

The first gate insulating film 111 and the second gate insulating film 112 may be formed to be spaced apart from each other, as illustrated in FIG. 2. For example, the first gate insulating film 111 and the second gate insulating film 112 may be spaced apart from each other in the first direction X1. Further, the first gate insulating film 111 and the second gate insulating film 112 may be formed to intersect (e.g., traverse) the first fin type pattern F1. For example, the first gate insulating film 111 and the second gate insulating film 112 may extend longitudinally in a second direction Y1 intersecting (e.g., traversing) the first direction X1. It will be understood that the first direction X1 and the second direction Y1 are horizontal directions that are parallel to a surface of the substrate 100. The first fin type pattern F1 may protrude from the substrate 100 in a vertical direction that is perpendicular to both the first direction X1 and the second direction Y1.

The first gate electrode G1 may be formed on the first gate insulating film 111, and the second gate electrode G2 may be formed on the second gate insulating film 112. As a result, the first gate electrode G1 and the second gate electrode G2 may be spaced apart from each other in the first direction X1. In addition, the first gate electrode G1 and the second gate electrode G2 may extend longitudinally in the second direction Y1.

For example, an insulating film and a conductive film may be sequentially formed on the substrate 100 and the first fin type pattern F1. Next, the insulating film and the conductive film may be patterned to form the first gate insulating film 111, the second gate insulating film 112, the first gate electrode G1, and the second gate electrode G2.

The first gate insulating film 111 and the second gate insulating film 112 may include a high-k material having a dielectric constant higher than that of the silicon oxide film. For example, the first gate insulating film 111 and the second gate insulating film 112 may include at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or a combination thereof, but the present inventive concept is not limited thereto.

Although FIG. 1 and FIG. 2 show only one fin type pattern F1 and two gate electrodes G1 and G2, the present inventive concept is not limited thereto. The method of fabricating the semiconductor device according to some embodiments may include forming multiple fin type patterns and/or multiple gate electrodes.

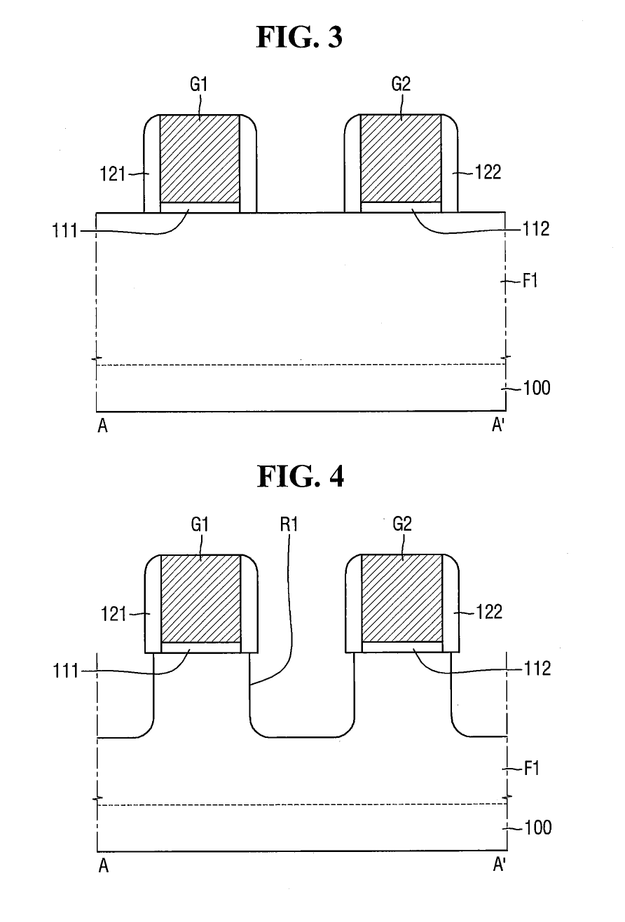

Referring to FIG. 3, a first spacer 121 and a second spacer 122 are formed.

The first spacer 121 may be formed on both sidewalls of the first gate insulating film 111, and both sidewalls of the first gate electrode G1. The second spacer 122 may be formed on both sidewalls of the second gate insulating film 112 and both sidewalls of the second gate electrode G2.

Although the first spacer 121 and the second spacer 122 are illustrated as a single film, each of the first spacer 121 and the second spacer 122 may include multiple films.

The first spacer 121 and the second spacer 122 may include, for example, at least one of silicon nitride (SiN), silicon oxynitride (SiON), silicon oxide (SiO2), silicon oxycarbonitride (SiOCN) or a combination thereof.

Referring to FIG. 4, a first recess R1 is formed in the first fin type pattern F1. The first recess R1 may be formed to be adjacent to the sidewalls of the first gate electrode G1 and the sidewalls of the second gate electrode G2. The first recess R1 may be formed between the first gate electrode G1 and the second gate electrode G2.

In some embodiments, the first recess R1 may be formed by an etching process which uses the first gate electrode G1, the second gate electrode G2, the first spacer 121, and the second spacer 122 as etching masks. As a result, the first recess R1 adjacent to the sidewalls of the first gate electrode G1 and the sidewalls of the second gate electrode G2 may be formed in the first fin type pattern F1. The etching process may include, for example, a reactive ion etching (RIE) process and/or a wet etching process, but the present inventive concept is not limited thereto. The first recess R1 may be formed by any appropriate process.

In some embodiments, the first recess R1 may include an undercut. For example, as illustrated in FIG. 4, the first recess R1 may include an undercut formed at the lower end of the first spacer 121 and at the lower end of the second spacer 122. A side of the first recess R1 may be recessed toward the substrate 100 and may expose a portion of a lower surface of the first spacer 121, as illustrated in FIG. 4.

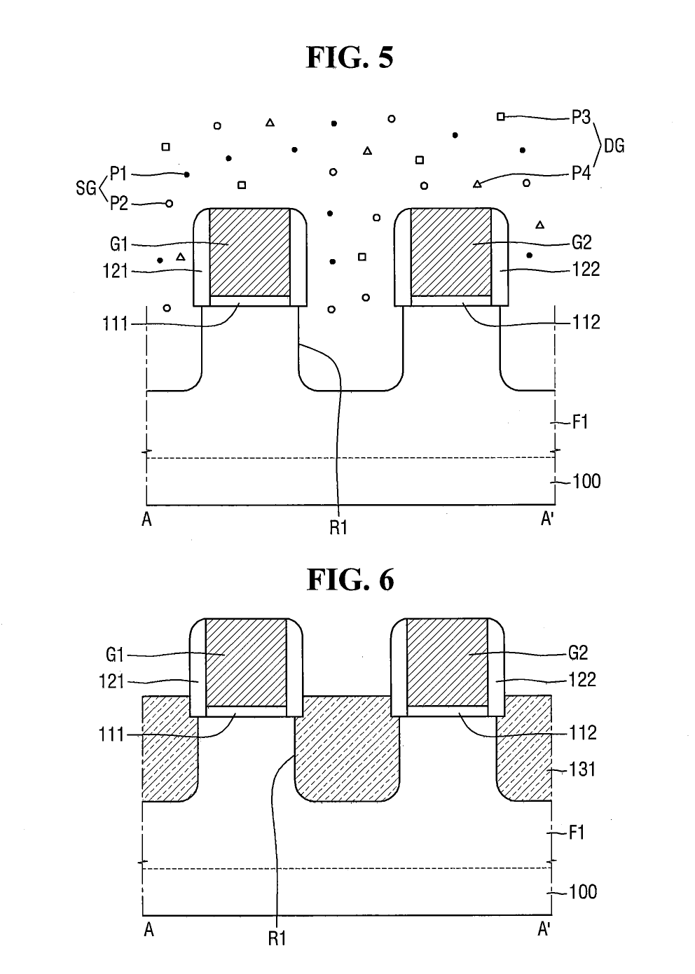

Referring to FIGS. 5 and 6, a first source/drain region 131 including p-type impurities is formed in the first recess R1.

The first source/drain region 131 may be formed by an epitaxial growth process (e.g., a selective EPI process) and a doping process performed in-situ with the epitaxial growth process. In some embodiments, an epitaxial growth process and a doping process performed concurrently. Throughout the specification, a selective EPI process will be discussed as an example of the epitaxial growth process.

For example, as illustrated in FIG. 5, by performing a chemical vapor deposition (CVD) process in which a first source gas SG and a first doping gas DG are used, the selective EPI process and the doping process may be performed (e.g., concurrently performed). In some embodiments, the selective EPI process and the doping process are performed by performing a single chemical vapor deposition (CVD) process that is performed in a single process chamber. Accordingly, it will be understood that the selective EPI process and the doping process may be performed in-situ.

In some embodiments, the first source gas SG may include a silicon (Si) precursor (P1) and a germanium (Ge) precursor (P2). As a result, a first source/drain region 131 including Si₁₋ₓGeₓ (where x is in the range of 0<x<1) may be formed. In some embodiments, x may be in the range from 0.4 to 0.7, but the present inventive concept is not limited thereto.

The silicon precursor (P1) may include, for example, but is not limited to, SiCl₂ (dichlorosilane). The germanium precursor (P2) may include, for example, but is not limited to, GeH₄ (germane).

The first doping gas DG may include a p-type impurity precursor. For example, the first doping gas DG may include a precursor of at least one of boron (B), aluminum (Al), gallium (Ga), indium (In), or a combination thereof.

In some embodiments, the first source gas SG may include the silicon precursor (P1) and the germanium precursor (P2), and the first doping gas DG may include a gallium (Ga) precursor (P3) and boron (B) precursor (P4). Accordingly, a first source/drain region 131 including Si₁₋ₓGeₓ (where x is in the range of 0<x<1) doped with gallium (Ga) and boron (B) may be formed. In some embodiments, the concentration of gallium (Ga) in the first source/drain region 131 may be about or greater than 1E20 cm⁻³. Also, in some embodiments, the concentration of boron (B) in the first source/drain region 131 may be about 0.1E20 cm⁻³ to about 5E20 cm⁻³.

The gallium precursor (P3) may include, for example, an organometallic compound containing gallium (Ga). The gallium precursor (P3) may include, for example, but is not limited to, at least one of Ga(CH₃)₃ (Trimethylgallium), Ga(C₂H₅)₃ (Triethylgallium), DMGIP (dimethylgallium isopropoxide) or combinations thereof.

The boron precursor (P4) may include, for example, but is not limited to, B₂H₆ (diborane).

In some embodiments, the first source/drain region 131 may be an elevated source/drain region. That is, an upper portion of the first source/drain region 131 may protrude upwardly from an uppermost surface of the first fin type pattern F1. An uppermost surface of the first source/drain region 131 may be at a level higher than an uppermost surface of the first fin type pattern F1, as illustrated in FIG. 6.

In some embodiments, the selective EPI process and the doping process may be performed at a process pressure of about 10 torr to about 250 torr and a process temperature of about 550° C. to about 740° C.

In some embodiments, the method may further include a baking process before performing the selective EPI process and the doping process. For example, the baking process may be performed using hydrogen (H₂) at a process pressure of about 150 torr to about 600 torr and a process temperature of about 650° C. to about 800° C. for about 3 minutes to about 5 minutes.

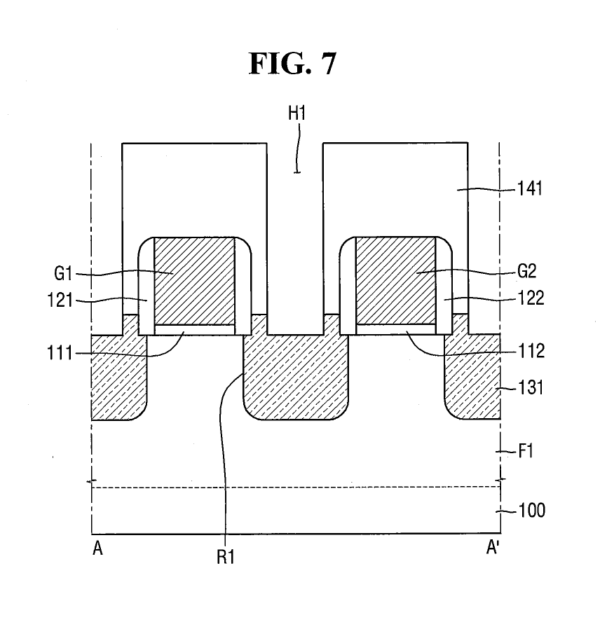

Referring to FIG. 7, a first interlayer insulating film 141 which exposes a portion of the first source/drain region 131 is formed. For example, the first interlayer insulating film 141 including a first contact hole H1 that exposes a portion of the first source/drain region 131 may be formed.

The first interlayer insulating film 141 may be formed on the resultant structure of FIG. 6. The first interlayer insulating film 141 may include, for example, at least one of silicon nitride (SiN), silicon oxynitride (SiON), silicon oxide (SiO2), silicon oxycarbonitride (SiOCN), or a combination thereof.

By etching a portion of the first interlayer insulating film 141, a first contact hole H1 that exposes a portion of the first source/drain region 131 may be formed.

Although FIG. 7 shows that the upper portion of the first source/drain region 131 is partially removed, the present inventive concept is not limited thereto. In some embodiments, while forming the first contact hole H1, the first source/drain region 131 may not be etched.

Although FIG. 7 shows that the first contact hole H1 does not expose the first spacer 121 and the second spacer 122, the present inventive concept is not limited thereto. In some embodiments, the first spacer 121 and the second spacer 122 may be partially etched while forming the first contact hole H1 and thus may be exposed through the first contact hole H1. The first contact hole H1 may be spaced apart from the first gate electrode G1 and the second gate electrode G2, and thus the first contact hole H1 may not expose the first gate electrode G1 and the second gate electrode G2, as illustrated in FIG. 7.

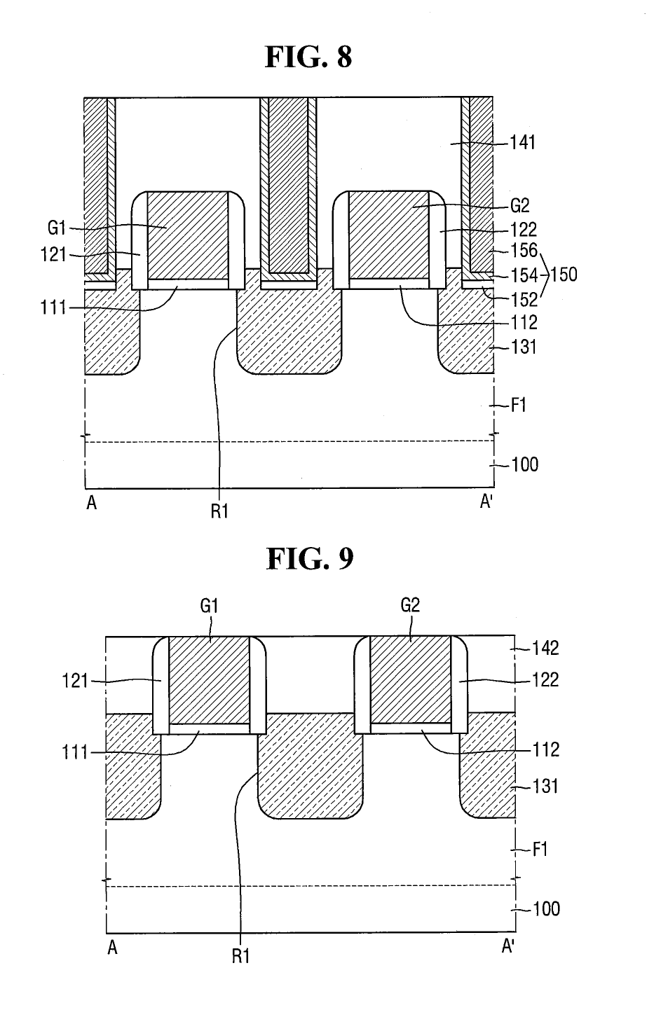

Referring to FIG. 8, a first contact 150 is formed in the first contact hole H1.

Since the first contact hole H1 exposes a portion of the first source/drain region 131, the first contact 150 may be in contact with the portion of the first source/drain region 131. As a result, the first contact 150 may electrically connect the first source/drain region 131 to at least one of conductive patterns of the semiconductor device, which will be formed later.

The first contact 150 may include, for example, a first silicide film 152, a first conductive film 154, and/or a second conductive film 156.

For example, the first silicide film 152 may be formed on the first source/drain region 131. The first silicide film 152 may include, for example, but is not limited to, at least one of Ti, Co, Ni, Mo, Pt or a combination thereof.

The first conductive film 154 may be formed along the upper surface of the first silicide film 152 and the sidewalls of the first contact hole H1. The first conductive film 154 may include, for example, but is not limited to, at least one of Ti, TiN or a combination thereof.

A second conductive film 156 may be formed on the first conductive film 154. In some embodiments, the second conductive film 156 may fill the first contact hole H1. The second conductive film 156 may include, for example, but is not limited to, at least one of W, Al, Cu, or a combination thereof.

The resistance of the source/drain contact may be determined by the height of the Schottky barrier. If the height of the Schottky barrier is lowered, the resistance of the source/drain contact may be lowered. To reduce the resistance of the source/drain contact, the height of the Schottky barrier may be lowered by doping the source/drain region (e.g., the first source/drain region 131).

The height of the Schottky barrier of a pFET may be lowered by doping p-type impurities (e.g., gallium (Ga)) into the source/drain region using, for example, an ion implantation process. After forming the first interlayer insulating film 141 of FIG. 7, p-type impurities may be doped into the first source/drain region 131. However, as appreciated by the present inventors, doping p-type impurities into the first source/drain region 131 after forming the first interlayer insulating film 141 can be complicated processes and may result in high fabrication cost.

The method of fabricating the semiconductor device according to some embodiments allows the source/drain region to be formed using the selective EPI process and the doping process performed in-situ (e.g., performed concurrently) with the selective EPI process, the contact resistance may be improved without high complexity and high fabrication cost. The method of fabricating a semiconductor device according to some embodiments may not include any doping process for doping p-type impurities into the source/drain region after the first interlayer insulating film 141 of FIG. 7 is formed. In some embodiments, no doping process for doping p-type impurities into the source/drain region is performed after the source/drain region is formed. In some embodiments, the source/drain region may only include p-type impurities that are doped while forming the source/drain region, and no additional p-type impurities are doped into the source/drain region after the source/drain region is formed.

Further, the method of fabricating the semiconductor device according to some embodiments may form a source/drain region including Si₁₋ₓGeₓ (here, x is in the range of 0<x<1) doped with both gallium (Ga) and boron (B). Since the solid solubility of gallium (Ga) to silicon germanium (SiGe) is higher than the solid solubility of boron (B) to silicon germanium (SiGe), the method may provide a source/drain region that more effectively lowers the height of the Schottky barrier. That is, the method may provide a source/drain region with more improved contact resistance than silicon germanium (SiGe) doped with only boron (B).

FIGS. 9 through 14 are views illustrating a method of fabricating a semiconductor device according to some embodiments of the present inventive concept. For the sake of convenience of explanation, the repeated description with reference to FIGS. 1 to 8 will be briefly described or omitted.

FIGS. 9 to 14 are cross-sectional views taken along the line A-A′ of FIG. 1 and illustrated processes performed after FIG. 6.

Referring to FIG. 9, a second interlayer insulating film 142 is formed on the first gate electrode G1 and the second gate electrode G2. In some embodiments, the second interlayer insulating film 142 may expose the first gate electrode G1 and the second gate electrode G2, as illustrated in FIG. 9.

The second interlayer insulating film 142 may be formed on the resultant structure of FIG. 6. The second interlayer insulating film 142 may include, for example, at least one of silicon nitride (SiN), silicon oxynitride (SiON), silicon oxide (SiO2), silicon oxycarbonitride (SiOCN), or a combination thereof.

A planarization process may be performed on the second interlayer insulating film 142. The planarization process may be performed until the upper surface of the first gate electrode G1 and the upper surface of the second gate electrode G2 are exposed. The planarization process may include, for example, a chemical mechanical polishing (CMP) process, but the present inventive concept is not limited thereto.

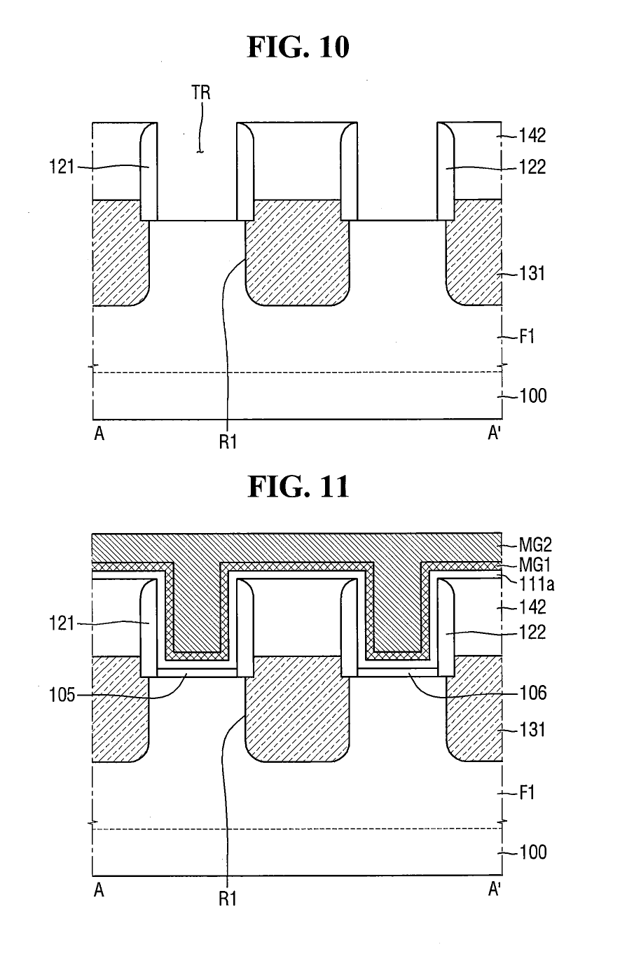

Referring to FIG. 10, the first gate insulating film 111, the second gate insulating film 112, the first gate electrode G1, and the second gate electrode G2 are removed.

As a result, trenches TR may be formed in regions (e.g., spaces) from which the first gate insulating film 111, the second gate insulating film 112, the first gate electrode G1, and the second gate electrode G2 are removed. The trenches TR that expose portions of the upper surface of the first fin type pattern F1 may be formed.

Referring to FIG. 11, a first interface film 105, a second interface film 106, a first insulating film 111a, a first metal film MG1, and a second metal film MG2 are formed inside the trenches TR and on the second interlayer insulating film 142.

The first interface film 105 may be formed on the first fin type pattern F1 between the first spacers 121, and the second interface film 106 may be formed on the first fin type pattern F1 between the second spacers 122.

The first interface film 105 and the second interface film 106 may include, for example, silicon oxide, but the present inventive concept is not limited thereto. The first interface film 105 and the second interface film 106 may include other materials depending on the type of the first fin type pattern F1, the type of the first insulating film 111a, and the like.

In some embodiments, the first interface film 105 and the second interface film 106 may be omitted.

The first insulating film 111a may be formed to extend along the profiles of the upper surface of the second interlayer insulating film 142, the sidewalls of the trench TR, the upper surface of the first interface film 105, and the upper surface of the second interface film 106, as illustrated in FIG. 11.

The first insulating film 111a may include, for example, a high-k material having a dielectric constant higher than that of the silicon oxide film. For example, the first insulating film 111a may include at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof, but the present inventive concept is not limited thereto.

A first metal film MG1 extending along the profiles of the upper surface and the sidewalls of the first insulating film 111a is formed, and a second metal film MG2 may be formed on the first metal film MG1. The first metal film MG1 may adjust the work function, and, in some embodiments, the second metal film MG2 may fill the space defined by the first metal film MG1.

The first metal film MG1 may include, for example, at least one of TiN, TaN, TiC, TaC, or a combination thereof. The second metal film MG2 may include, for example, at least one of W, Al, or a combination thereof. In some embodiments, the first metal film MG1 or the second metal film MG2 may include silicon (Si), silicon germanium (SiGe), or the like rather than the metal.

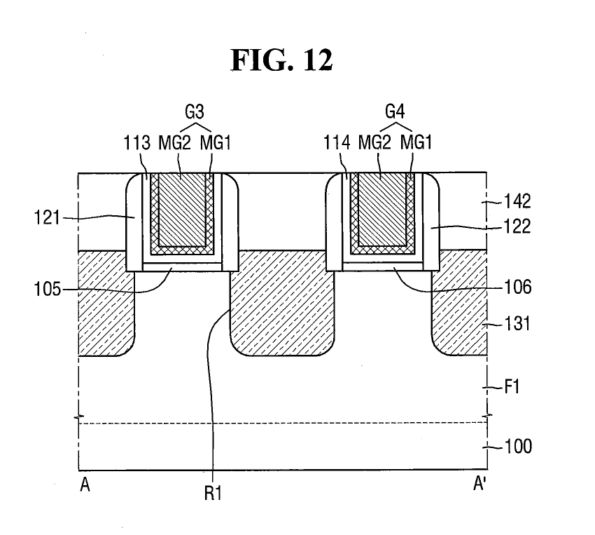

Referring to FIG. 12, a planarization process may be performed until the upper surface of the second interlayer insulating film 142 is exposed.

The planarization process may include, for example, a CMP process, but the present inventive concept is not limited thereto.

A third gate insulating film 113 and a third gate electrode G3 may be formed on the first interface film 105. Further, a fourth gate insulating film 114 and a fourth gate electrode G4 may be formed on the second interface film 106.

In some embodiments, the third gate insulating film 113 may be formed to extend along the upper surface of the first interface film 105 and the sidewalls of the trench (TR of FIG. 10), as illustrated in FIG. 12. Further, the first metal film MG1 extending along the upper surface and the sidewalls of the third gate insulating film 113, and the third gate electrode G3 including the second metal film MG2 on the first metal film MG1 may be formed.

Likewise, the fourth gate insulating film 114 extending along the upper surface of the second interface film 106 and the sidewalls of the trench (TR of FIG. 10) may be formed, as illustrated in FIG. 12. In addition, the first metal film MG1 extending along the upper surface and the sidewalls of the fourth gate insulating film 114, and the fourth gate electrode G4 including the second metal film MG2 on the first metal film MG1 may be formed.

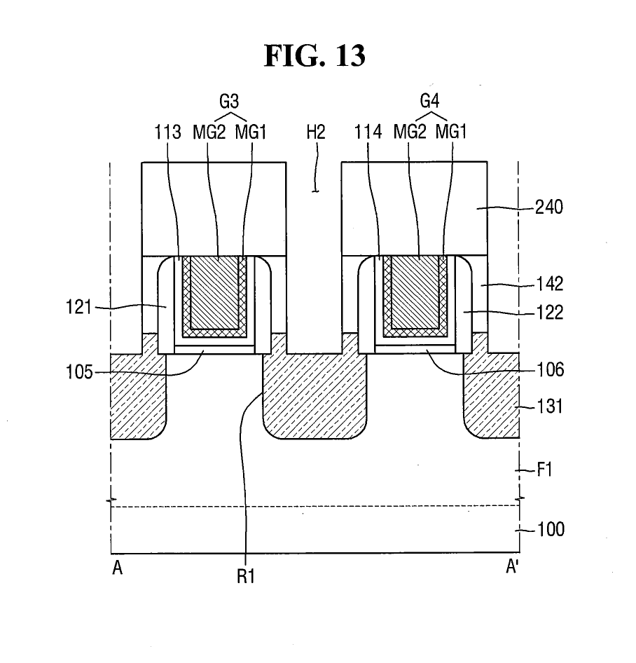

Referring to FIG. 13, a third interlayer insulating film 240 is formed on the second interlayer insulating film 142, the third gate electrode G3, and the fourth gate electrode G4.

The third interlayer insulating film 240 may include, for example, the same material as the second interlayer insulating film 142, but the present inventive concept is not limited thereto.

A second contact hole H2 may be formed to expose a portion of the first source/drain region 131 by etching a portion of the second interlayer insulating film 142 and a portion of the third interlayer insulating film 240.

Therefore, the second interlayer insulating film 142 and the third interlayer insulating film 240 may be formed to expose a portion of the first source/drain region 131.

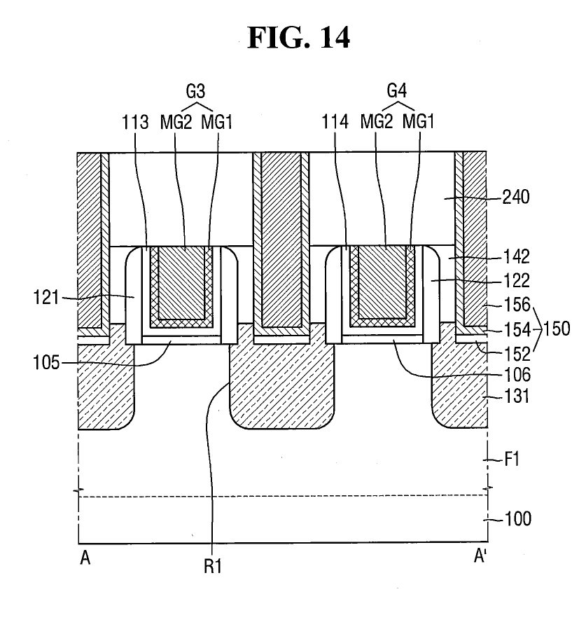

Referring to FIG. 14, the first contact 150 is formed in the second contact hole H2.

Since the formation of the first contact 150 is substantially the same as that described above in the description of FIG. 8, the detailed description thereof will not be provided.

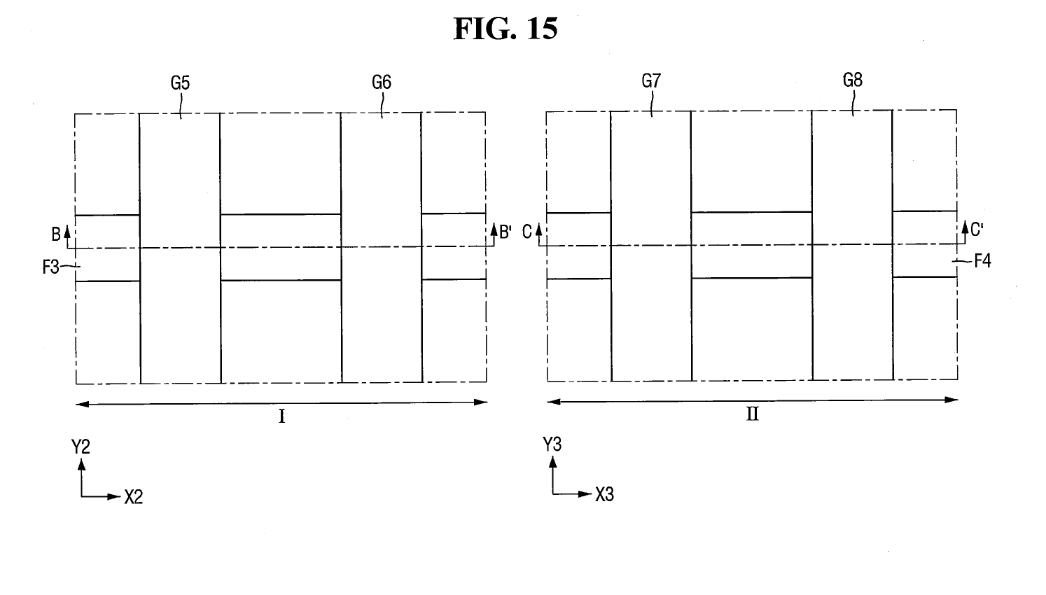

FIGS. 15 to 25 are views illustrating a method of fabricating a semiconductor device according to some embodiments of the present inventive concept. For the sake of convenience of explanation, the repeated description will be briefly described or omitted.

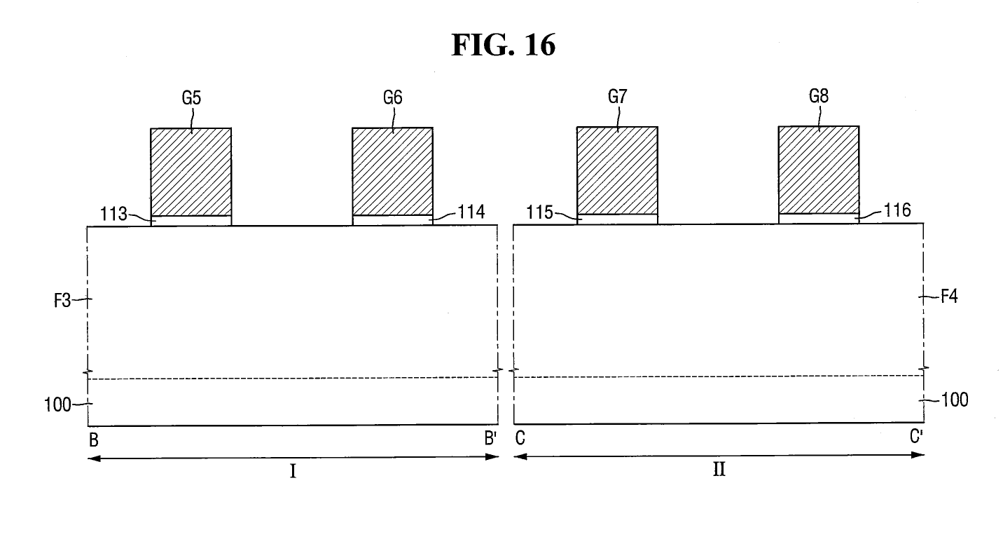

FIG. 15 is a layout illustrating the method of fabricating the semiconductor device according to some embodiments of the present inventive concept. FIGS. 16 to 25 are cross-sectional views taken along the lines B-B′ and C-C′ of FIG. 15.

Referring to FIGS. 15 and 16, a second fin type pattern F3 and a third fin type pattern F4 are formed on the substrate 100.

The substrate 100 may include a first region I and a second region II. The first region I and the second region II may be regions that are spaced apart from each other, but the present inventive concept is not limited thereto, and the first region I and the second region II may be adjacent regions. In some embodiments, the first region I may contact the second region II.

In some embodiments, the first region I of the substrate 100 is the region in which a pFET is formed, and the second region II of the substrate 100 may be the region in which an nFET is formed.

The second fin type pattern F3 protrudes from the first region I of the substrate 100 and may extend longitudinally in a third direction X2. The third fin type pattern F4 protrudes from the second region II of the substrate 100 and may extend longitudinally in a fifth direction X3.

The second fin type pattern F3 and the third fin type pattern F4 may be portions of the substrate 100. In some embodiments, each of the second fin type pattern F3 and the third fin type pattern F4 may include an epitaxial layer that is grown from the substrate 100.

Subsequently, the third gate insulating film 113, the fourth gate insulating film 114, the fifth gate electrode G5, and the sixth gate electrode G6 are formed on the second fin type pattern F3. Further, the fifth gate insulating film 115, the sixth gate insulating film 116, the seventh gate electrode G7, and the eighth gate electrode G8 are formed on the third fin type pattern F4.

The third gate insulating film 113 and the fourth gate insulating film 114 may be spaced apart from each other in the third direction X2. Further, the third gate insulating film 113 and the fourth gate insulating film 114 may extend longitudinally in a fourth direction Y2 intersecting (e.g., traversing) the third direction X2.

The fifth gate insulating film 115 and the sixth gate insulating film 116 may be spaced apart from each other in the fifth direction X3. Further, the fifth gate insulating film 115 and the sixth gate insulating film 116 may extend longitudinally in a sixth direction Y3 intersecting (e.g., traversing) the fifth direction X3. It will be understood that the third direction X2, the fourth direction Y2, the fifth direction X3, and the sixth direction Y3 are all horizontal directions that are parallel to a surface of the substrate 100. The second fin type pattern F3 and the third fin type pattern F4 may protrude from the substrate 100 in a vertical direction that is perpendicular to the third direction X2, the fourth direction Y2, the fifth direction X3, and the sixth direction Y3.

In some embodiments, the third direction X2 and the fifth direction X3 may be substantially the same, and the fourth direction Y2 and the sixth direction Y3 may be substantially the same, but the present inventive concept is not limited thereto. For example, the third direction X2 and the fifth direction X3 may be different from each other, and the fourth direction Y2 and the sixth direction Y3 may be different from each other.

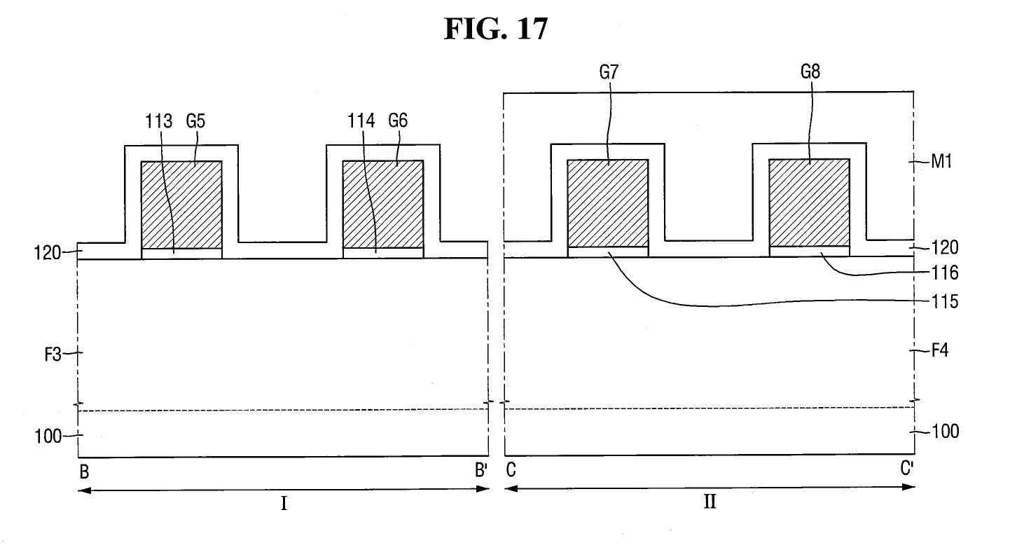

Referring to FIG. 17, the second insulating film 120 is formed on the resultant structure of FIG. 16.

Thus, the second insulating film 120 may be formed to extend along the profiles of the upper surface of the second fin type pattern F3, the upper surface of the third fin type pattern F4, the upper surface and the sidewalls of the fifth gate electrode G5, the upper surface and the sidewalls of the sixth gate electrode G6, the upper surface and the sidewalls of the seventh gate electrode G7, and the upper surface and the sidewalls of the eighth gate electrode G8.

The second insulating film 120 may include, for example, at least one of silicon nitride (SiN), silicon oxynitride (SiON), silicon oxide (SiO2), silicon oxycarbonitride (SiOCN) or combinations thereof.

A first mask pattern M1 which exposes the second insulating film 120 on the first region I of the substrate 100 may be formed. That is, the first mask pattern M1 may be formed on the second region II of the substrate 100, thereby exposing the second insulating film 120 on the first region I.

The first mask pattern M1 may include, for example, a photoresist, but the present inventive concept is not limited thereto.

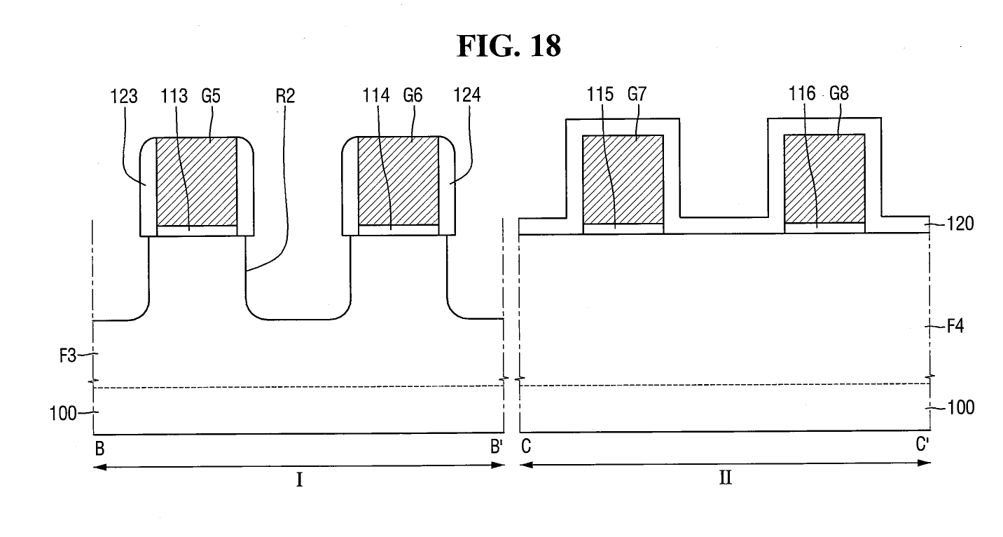

Referring to FIG. 18, a third spacer 123, a fourth spacer 124, and a second recess R2 are formed.

Third spacers 123 and fourth spacers 124 may be formed by an etching process (e.g., an etching process to etch the second insulating film 120) in which the first mask pattern M1 is used as an etching mask. As a result, the third spacers 123 may be formed on both sidewalls of the third gate insulating film 113 and both sidewalls of the fifth gate electrode G5. Further, the fourth spacers 124 may be formed on both sidewalls of the fourth gate insulating film 114 and both sidewalls of the sixth gate electrode G6.

The second recess R2 may be formed by an etching process in which the fifth gate electrode G5, the sixth gate electrode G6, the third spacers 123, and the fourth spacers 124 are used as the etching masks. As a result, a second recess R2 adjacent to the sidewalls of the fifth gate electrode G5 and the sidewalls of the sixth gate electrode G6 may be formed in the second fin type pattern F3.

Subsequently, the first mask pattern M1 may be removed.

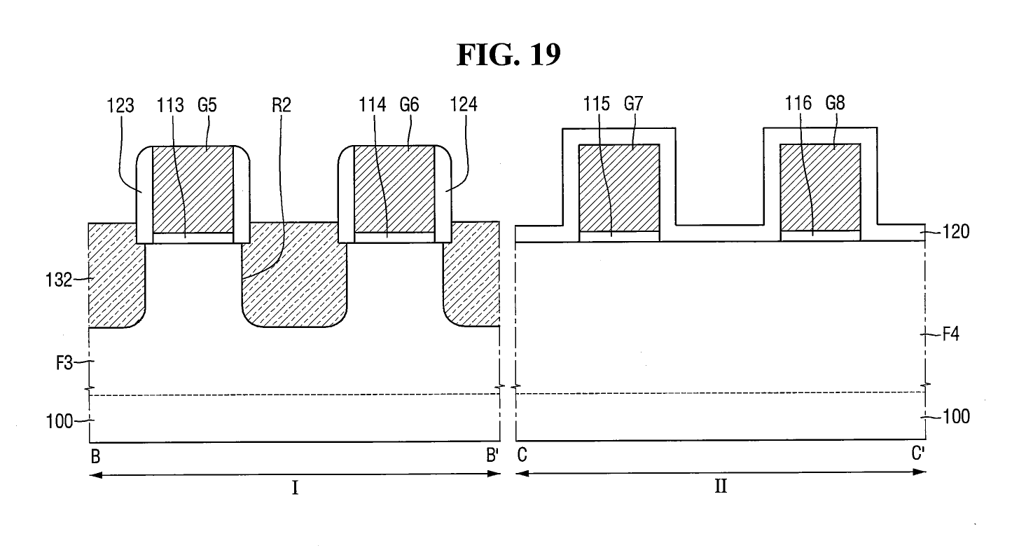

Referring to FIG. 19, a second source/drain region 132 including p-type impurities is formed in the second recess R2.

The second source/drain region 132 may be formed, using a first select EPI process and a first doping process performed in-situ with the first select EPI process. In some embodiments, the first select EPI process and the first doping process may be performed concurrently.

Since the formation of the second source/drain region 132 is substantially the same as or similar to the formation of the first source/drain region 131 described with reference to FIG. 6, the detailed description thereof will be omitted.

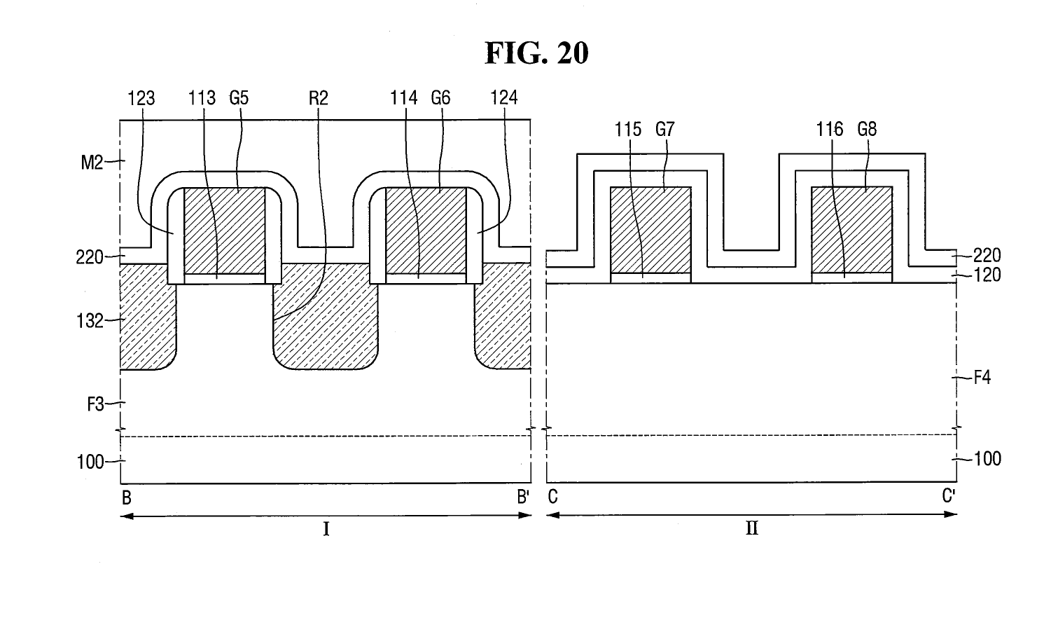

Referring to FIG. 20, the third insulating film 220 is formed on the resultant structure of FIG. 19.

In the first region I of the substrate 100, the third insulating film 220 may extend along the profiles of the upper surface of the second source/drain region 132, the upper surfaces of the third spacers 123, the upper surfaces of the fourth spacers 124, the upper surface of the fifth gate electrode G5, and the upper surface of the sixth gate electrode G6. In the second region II of the substrate 100, the third insulating film 220 may extend along the profile of the upper surface of the second insulating film 120.

The third insulating film 220 may include, for example, at least one of silicon nitride (SiN), silicon oxynitride (SiON), silicon oxide (SiO2), silicon oxycarbonitride (SiOCN) or combinations thereof.

A second mask pattern M2 which exposes the third insulating film 220 on the second region II is formed. That is, the second mask pattern M2 is formed on the first region I of the substrate 100 and may expose the third insulating film 220 on the second region.

The second mask pattern M2 may include, for example, a photoresist, but the present inventive concept is not limited thereto.

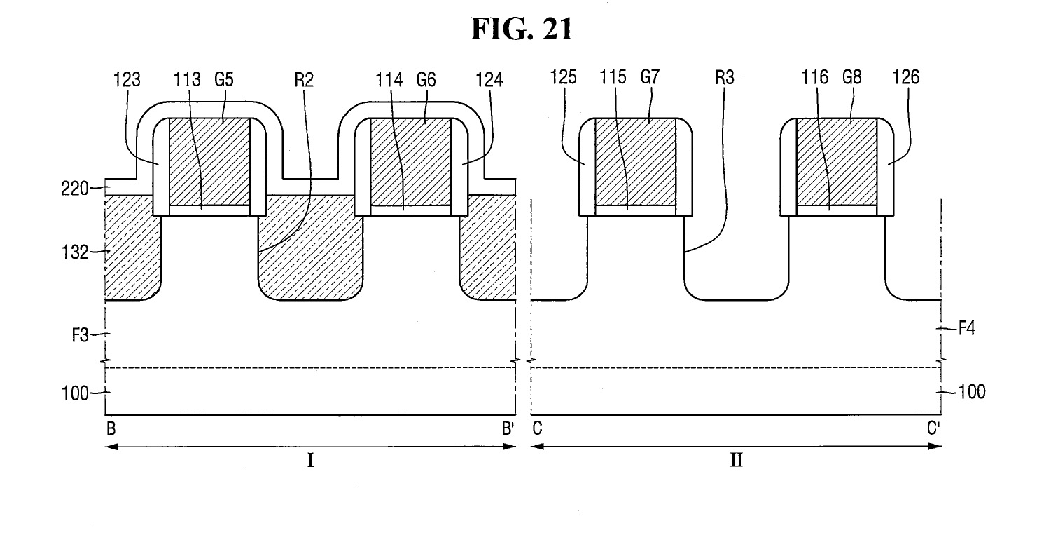

Referring to FIG. 21, fifth spacers 125, sixth spacers 126, and a third recess R3 are formed.

The fifth spacers 125 and the sixth spacers 126 may be formed by an etching process (e.g., an etching process to etch the third insulating film 220) in which the second mask pattern M2 is used as an etching mask. As a result, the fifth spacers 125 may be formed on both sidewalls of the fifth gate insulating film 115 and both sidewalls of the seventh gate electrode G7. The sixth spacers 126 may be formed on both sidewalls of the sixth gate insulating film 116 and both sidewalls of the eighth gate electrode G8.

The thickness of the fifth spacers 125 and the thickness of the sixth spacers 126 are illustrated as being similar to the thickness of the third spacers 123 and the thickness of the fourth spacers 124. However, this is only for convenience of explanation, and the present inventive concept is not limited thereto. The fifth spacers 125 and the sixth spacers 126 may have thicknesses different from those of the third spacers 123 and the fourth spacers 124.

The third recess R3 may be formed by an etching process using the seventh gate electrode G7, the eighth gate electrode G8, the fifth spacer 125 and the sixth spacer 126 as the etching masks. As a result, a third recess R3 adjacent to the sidewalls of the seventh gate electrode G7 and the sidewalls of the eighth gate electrode G8 may be formed in the third fin type pattern F4.

Subsequently, the second mask pattern M2 may be removed.

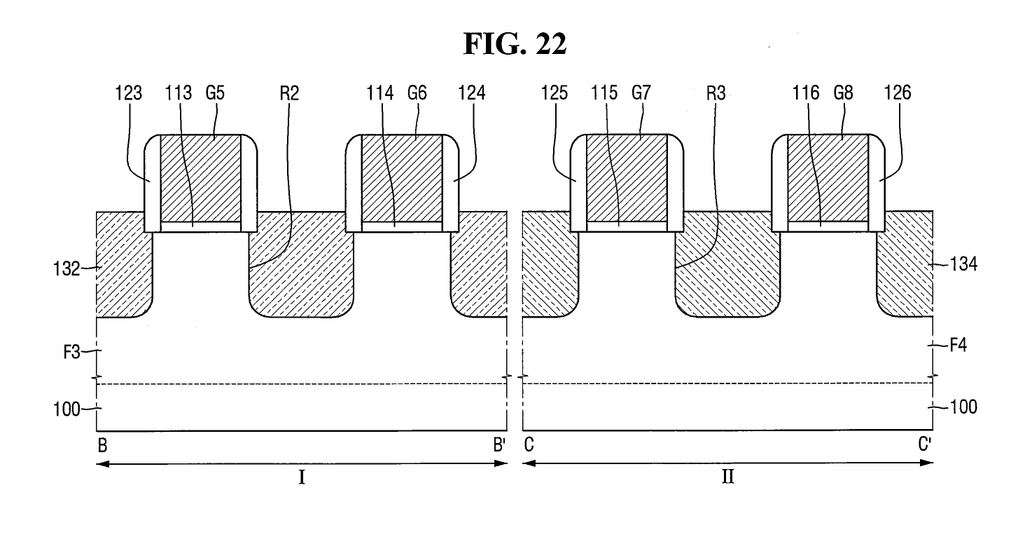

Referring to FIG. 22, a third source/drain region 134 is formed in the third recess R3.

For example, a second selective EPI process may be performed to form a third source/drain region 134 in the third recess R3. The second selective EPI process may include, for example, a chemical vapor deposition process.

In some embodiments, the third source/drain region 134 may be an elevated source/drain region. That is, the uppermost portion of the third source/drain region 134 may protrude upwardly from the uppermost surface of the third fin type pattern F4. The uppermost surface of the third source/drain region 134 may be at a level higher than the uppermost surface of the third fin type pattern F4, as illustrated in FIG. 22.

In some embodiments, the method may further include formation of a fourth insulating film (not illustrated) after forming the third source/drain region 134. For example, after forming the third source/drain region 134, a fourth insulating film including, for example, at least one of silicon nitride (SiN), silicon oxynitride (SiON), silicon oxide (SiO2), silicon oxycarbonitride (SiOCN), or a combination thereof may be formed.

Although FIG. 22 shows that the third insulation film 220 and the fourth insulation film are removed, but this is only for convenience of explanation, and the present inventive concept is not limited thereto. For example, the third insulating film 220 and the fourth insulating film may remain on the first region I and/or the second region II of the substrate 100.

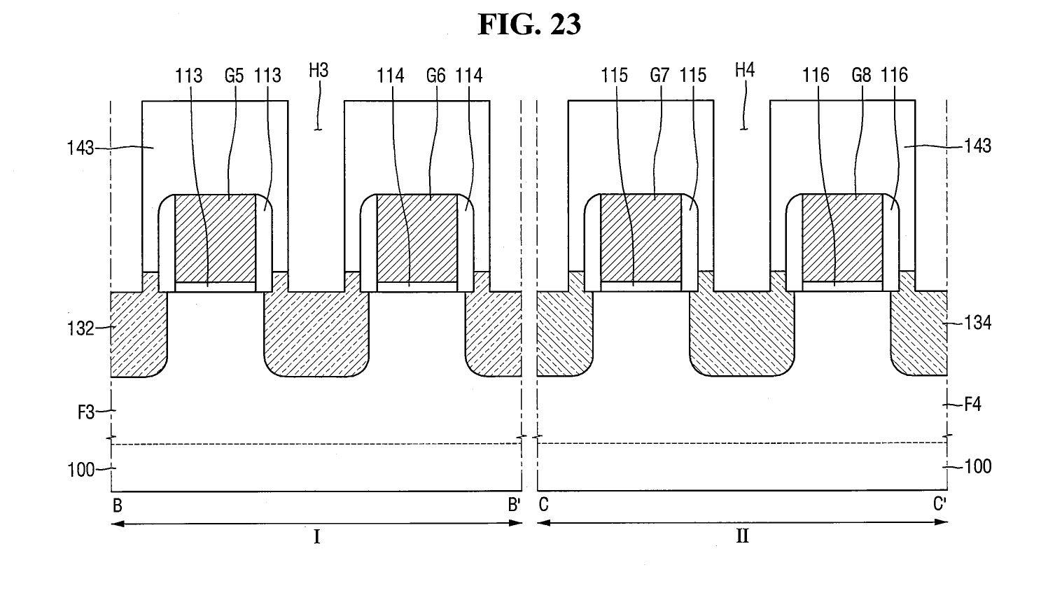

Referring to FIG. 23, a fourth interlayer insulating film 143 is formed to expose portions of the second source/drain region 132 and portions of the third source/drain region 134.

For example, the fourth interlayer insulating film 143 may be formed to include a third contact hole H3 that exposes a portion of the second source/drain region 132, and a fourth contact hole H4 that exposes a portion of the third source/drain region 134.

The fourth interlayer insulating film 143 may be formed on the resultant structure of FIG. 22. The fourth interlayer insulating film 143 may include, for example, at least one of silicon nitride (SiN), silicon oxynitride (SiON), silicon oxide (SiO2), silicon oxycarbonitride (SiOCN), or a combination thereof.

A portion of the fourth interlayer insulating film 143 may be etched to form the third contact hole H3 exposing a portion of the second source/drain region 132 and the fourth contact hole H4 exposing a portion of the third source/drain region 134.

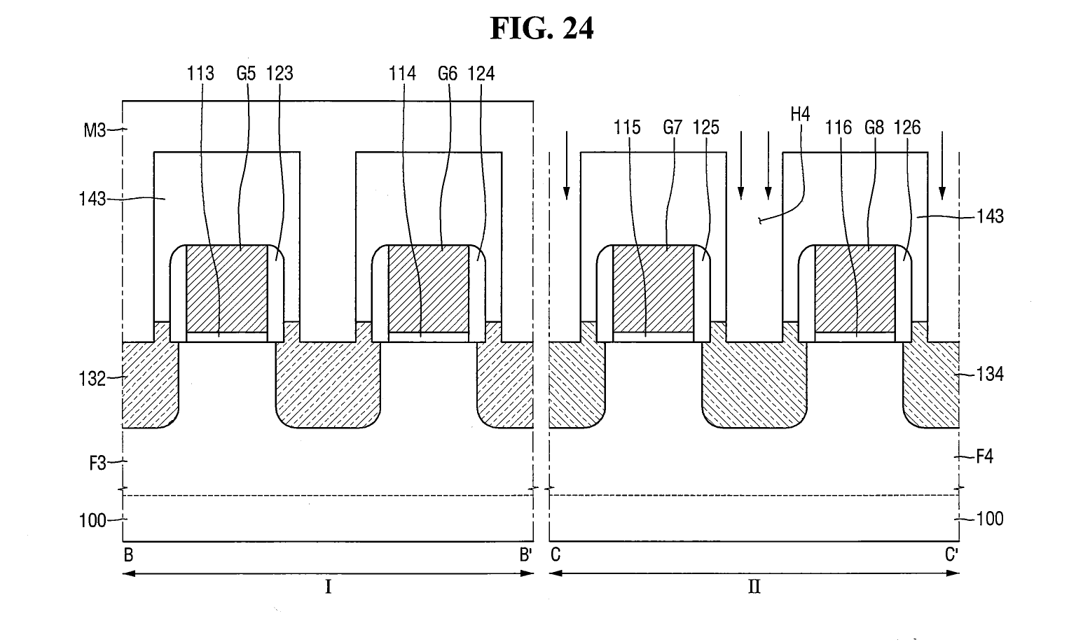

Referring to FIG. 24, a third mask pattern M3 exposing a portion of the fourth interlayer insulating film 143 and the third source/drain region 134 formed on the second region II of the substrate 100 is formed. That is, the third mask pattern M3 is formed on the first region I of the substrate 100 and may expose a portion of the third source/drain region 134.

A second doping process to dope first n-type impurities into the exposed third source/drain region 134 may be performed. For example, as illustrated, the first n-type impurities may be doped into the third source/drain region 134 through the fourth contact hole H4.

The first n-type impurities may include, for example, at least one of phosphorus (P), arsenic (As), antimony (Sb), or a combination thereof. Further, the second doping process may be performed using, for example, an ion implantation process.

Subsequently, the third mask pattern M3 may be removed.

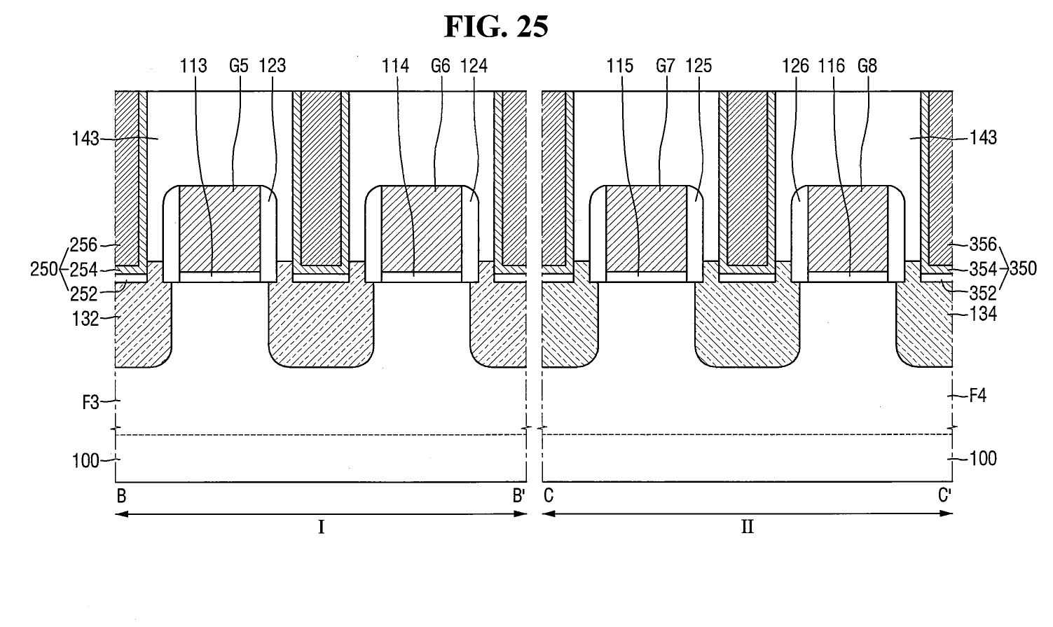

Referring to FIG. 25, the second contact 250 is formed in the third contact hole H3, and the third contact 350 is formed in the fourth contact hole H4.

The second contact 250 may include, for example, a second silicide film 252, a third conductive film 254, and a fourth conductive film 256. The third contact 350 may include, for example, a third silicide film 352, a fifth conductive film 354, and a sixth conductive film 356.

Since the formation of the second contact 250 and the third contact 350 is substantially the same as the formation of the first contact 150 described with reference to FIG. 8, the detailed description thereof will not be provided.

In some embodiments, the second contact 250 and the third contact 350 may be formed to have substantially the same structure and to include substantially the same materials, but the present inventive concept is not limited thereto. In some embodiments, the second contact 250 and the third contact 350 may include different materials.

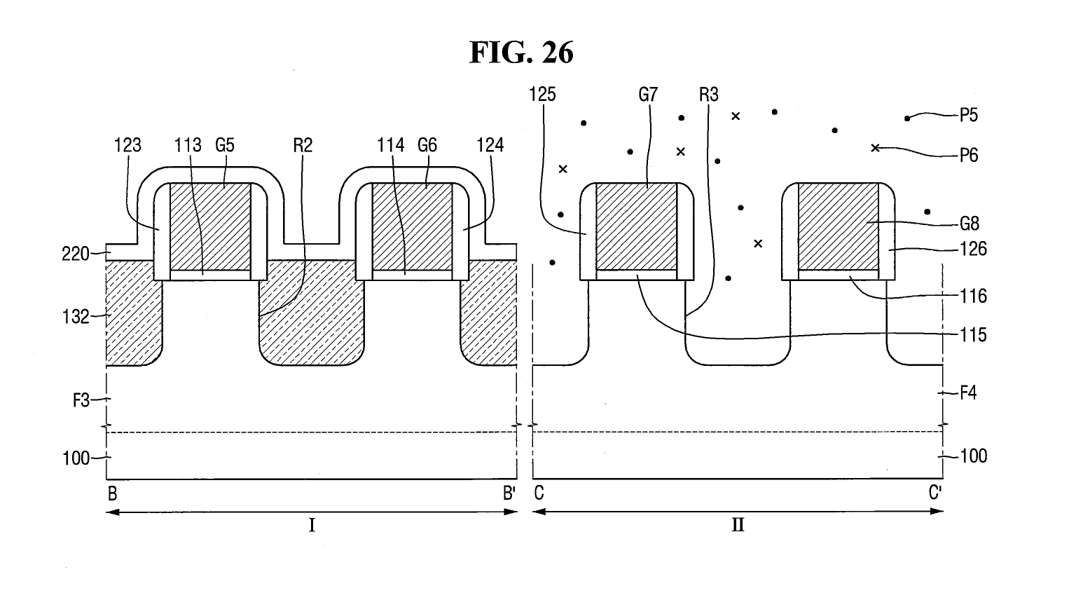

FIG. 26 is a view illustrating a method of fabricating a semiconductor device according to some embodiments of the present inventive concept. For the sake of convenience of explanation, the repeated description will be briefly explained or omitted.

FIG. 26 is a cross-sectional view taken along the lines B-B′ and C-C′ of FIG. 15 and illustrates processes performed after FIG. 21.

Referring to FIGS. 26 and 22, a third source/drain region 134 including the second n-type impurities is formed in the third recess R3.

The second n-type impurities may include, for example, at least one of phosphorus (P), arsenic (As), antimony (Sb), or a combination thereof.

The third source/drain region 134 may be formed, using a second selective EPI process and a third doping process performed in-situ with the second selective EPI process. In some embodiments, the second selective EPI process and the third doping process may be performed concurrently.

For example, as illustrated in FIG. 26, by performing a chemical vapor deposition process using a second source gas P5 and a second doping gas P6, the second selective EPI process and the third doping process may be performed.

In some embodiments, the second source gas P5 may include a silicon (Si) precursor. As a result, the third source/drain region 134 including silicon (Si) may be formed. The silicon precursor may include, for example, but is not limited to, SiCl₂ (dichlorosilane).

The second doping gas P6 may include an n-type impurity precursor. For example, the second doping gas P6 may include at least one precursor of phosphorus (P), arsenic (As), antimony (Sb), or a combination thereof.

In some embodiments, the second source gas P5 includes a silicon precursor, and the second doping gas P6 may include a phosphorous precursor. Accordingly, the third source/drain region 134 containing silicon (Si) doped with phosphorus (P) may be formed.

Subsequently, the same processes as described with reference to FIGS. 22 to 25 may be performed.

The above-disclosed subject matter is to be considered illustrative, and not restrictive, and the appended claims are intended to cover all such modifications, enhancements, and other embodiments, which fall within the true spirit and scope of the inventive concept. Thus, to the maximum extent allowed by law, the scope is to be determined by the broadest permissible interpretation of the following claims and their equivalents, and shall not be restricted or limited by the foregoing detailed description.

What is claimed is:

1. A method of fabricating a semiconductor device, the method comprising:
forming an active pattern on a substrate;
forming a gate electrode traversing the active pattern on the active pattern;
forming a recess adjacent to a sidewall of the gate electrode in the active pattern; and
performing a chemical vapor deposition process using a source gas and a doping gas to form a source/drain region in the recess,
wherein the source gas comprises a silicon precursor and a germanium precursor, and
wherein the doping gas comprises a gallium precursor and a boron precursor.

2. The method of claim 1, further comprising:
forming an interlayer insulating film comprising a contact hole that exposes a portion of the source/drain region; and
forming a contact in the contact hole,
wherein no doping process for doping p-type impurities into the source/drain region is performed after forming the interlayer insulating film.

3. The method of claim 1, wherein the active pattern has a fin shape protruding from the substrate.

4. The method of claim 1, wherein the silicon precursor comprises SiCl₂ (dichlorosilane), and the germanium precursor comprises GeH₄ (germane).

5. The method of claim 1, wherein the gallium precursor comprises an organometallic compound comprising gallium.

6. The method of claim 1, wherein the boron precursor comprises B₂H₆ (diborane).

7. The method of claim 1, wherein the source/drain region comprises Si₁₋ₓGeₓ, and x is in a range of 0.4 to 0.7, and
wherein the source/drain region further comprises gallium and boron.

8. The method of claim 7, wherein performing the chemical vapor deposition process comprises performing a single chemical vapor deposition process to form the source/drain region.

9. The method of claim 7, wherein the source/drain region comprises a concentration of gallium of about 1E20 cm⁻³ or more.

10. The method of claim 7, wherein the source/drain region comprises a concentration of boron of about 0.1E20 cm⁻³ to about 5E20 cm³.

11. A method of fabricating a semiconductor device, the method comprising:
forming an active pattern on a substrate;
forming a gate electrode traversing the active pattern on the active pattern;
forming a recess adjacent a sidewall of the gate electrode in the active pattern; and
forming a source/drain region in the recess by performing an epitaxial growth process and a doping process in-situ,
wherein the source/drain region comprises Si₁₋ₓGeₓ doped with gallium and boron.

12. The method of claim 11, wherein x is in a range of 0.4 to 0.7.

13. The method of claim 11, wherein the epitaxial growth process and the doping process are performed by a single chemical vapor deposition process.

14. The method of claim 11, wherein no doping process for doping p-type impurities into the source/drain region is performed after forming the source/drain region.

15. A method of fabricating a semiconductor device, the method comprising:
forming a first active pattern and a second active pattern on a substrate;
forming a first recess in the first active pattern;
forming a first source/drain region comprising p-type impurities in the first recess by performing a first epitaxial growth process and a first doping process concurrently;
forming a second recess in the second active pattern;
performing a second epitaxial growth process to form a second source/drain region in the second recess; and
performing a second doping process to dope first n-type impurities into the second source/drain region, after forming the second source/drain region,
wherein the first source/drain region comprising the p-type impurities is formed without performing a doping process for doping the p-type impurities into the first source/drain region after forming the first source/drain region.

16. The method of claim 15, wherein the first source/drain region comprises Si₁₋ₓGeₓ doped with gallium and boron.

17. The method of claim 16, wherein x is in a range of 0.4 to 0.7, and
wherein the first source/drain region comprises a concentration of gallium of about 1E20 cm⁻³ or more.

18. The method of claim 15, wherein performing the second doping process comprises performing an ion implantation process.

19. The method of claim 15, further comprising:
after forming the second source/drain region, forming an interlayer insulating film including a first contact hole and a second contact hole, the first contact hole exposing a portion of the first source/drain region, and the second contact hole exposing a portion of the second source/drain region,
wherein performing the second doping process comprises doping the first n-type impurities into the second source/drain region through the second contact hole.

20. The method of claim 15, wherein forming the second source/drain region comprises doping second n-type impurities into the second source/drain region using a third doping process performed concurrently with the second epitaxial growth process.
